(19) United States
(12) Patent Application Publication
(10) Pub. No.: US 2009/0272995 A1
(43) Pub. Date: Nov. 5, 2009

(54) RESIN COMPOSITION FOR OPTICAL SEMICONDUCTOR ELEMENT ENCAPSULATION, AND OPTICAL SEMICONDUCTOR DEVICE PRODUCED BY USING THE SAME

(75) Inventors: Hisataka Ito, Ibaraki-shi (JP); Hideyuki Usui, Ibaraki-shi (JP); Naoto Hirosaki, Tsukuba-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: NITTO DENKO CORPORATION, Ibaraki-shi, Osaka (JP); NATIONAL INSTITUTE FOR MATERIALS SCIENCE, Tsukuba-shi, Ibaraki (JP)

(21) Appl. No.: 12/088,827

(22) PCT Filed: Sep. 27, 2006
(86) PCT No.: PCT/JP2006/319116

§ 371 Date: Nov. 12, 2008

(30) Foreign Application Priority Data
Sep. 30, 2005 (JP) 2005-285737

(51) Int. Cl. H01L 33/00; C09K 11/02

(52) U.S. Cl. 257/98; 252/301.36; 257/E33.067

(57) ABSTRACT

An epoxy resin composition for optical semiconductor element encapsulation includes an epoxy resin (Component (A)) mainly containing an epoxy compound represented by a specific structural formula (1), a curing agent (Component (B)), and at least one of an oxynitride phosphor and a nitride phosphor (Component (C)). Therefore, the phosphor component (C) is uniformly dispersed in the epoxy resin composition without segregation. Thus, the resin composition serves as an excellent optical semiconductor element encapsulation material which has an adequate light diffusion property and a high light transmittance and permits a reduction in internal stress. Therefore, a light emitting diode element encapsulated with the epoxy resin composition is capable of stably emitting light, and satisfactorily performs its functions.

### TECHNICAL FIELD

White light emitting diodes (LEDs) for use in LED display devices, backlight sources, displays, indicators and the like are generally produced by encapsulating a blue LED element with a transparent thermosetting resin containing a phosphor. The present invention relates to a resin composition which has a light diffusing effect in an optical semiconductor device utilizing stable secondary light emission and permits a reduction in internal stress, and to an optical semiconductor device.

### BACKGROUND ART

A potting encapsulation resin composition which provides a yellow phosphor in the vicinity of the blue LED element in the LED light emitting device utilizing the secondary light emission is prepared by mixing a powdery phosphor and a liquid potting resin for potting (see Patent Document 1).

Patent Document 1: Japanese Unexamined Patent Publication No. HEI10 (1998)-93146.

### DISCLOSURE OF THE INVENTION

### Problems to be Solved by the Invention

Encapsulation of an LED device utilizing a short wavelength suffers from a problem associated with light resistance, and requires use of a resin having a high light transmittance and a high heat resistance.

The yellow phosphor has relatively high efficiency, but has poor color rendering properties. Where the aforementioned encapsulation resin composition is employed as a potting encapsulation resin, it is problematic that the dispersibility of particles of the powdery phosphor is uneven due to sedimentation of the particles during curing of the resin. Further, where a powdery resin composition for optical semiconductor element encapsulation is blended with the powdery phosphor for use as an encapsulation material, uneven flow occurs during transfer molding. If the powdery phosphor is directly added to and mixed with the resin composition in a mixing vessel, the powdery phosphor which has a greater specific gravity is liable to experience sedimentation and segregation when the resulting mixture is received in a molten state. This often results in uneven concentration of the phosphor, thereby causing a problem such that emitted light is observed as having an uneven color. Further, a diffusion effect provided by the particles of the powdery phosphor per se depends upon the content of the phosphor. Furthermore, a product resin-encapsulated by curing the encapsulation material has a great internal stress. From the viewpoint of the light emission efficiency of the light emitting device, it is difficult to employ an encapsulation material which satisfactorily meets the requirements for the diffusion effect and the reduction in stress.

Where white LEDs are employed as a cluster of LEDs of a display device, for example, it is problematic that light beams emitted from the respective LEDs have color variations. Therefore, LEDs having little color variation in emitted light are selected to provide to the display device. However, this results in a reduction in production yield.

In view of the foregoing, it is an object of the present invention to provide an optical semiconductor element encapsulation resin composition which has a high light transmittance and an adequate light diffusion property and permits a reduction in internal stress, and to provide an optical semiconductor device produced by using the resin composition.

### Means for Solving the Problems

According to a first aspect of the present invention to achieve the aforementioned object, a resin composition for optical semiconductor element encapsulation comprises the following components (A) to (C):

(A) an epoxy resin mainly containing an epoxy compound represented by the following structural formula (1):

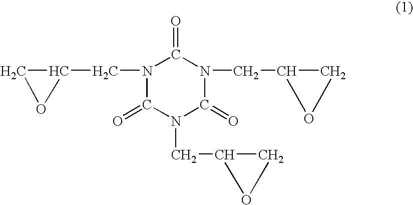

(B) a curing agent; and
(c) at least one of an oxynitride phosphor and a nitride phosphor (an oxynitride phosphor and/or a nitride phosphor).

According to a second aspect of the present invention, there is provided an optical semiconductor device produced by encapsulating an optical semiconductor element with the aforementioned optical semiconductor element encapsulation resin composition.

The inventors of the present invention conducted intensive studies to provide an optical semiconductor element encapsulation material which is excellent in stress reducing effect, heat resistance and light resistance and suppresses sedimentation and segregation of a powdery phosphor to ensure uniform dispersion of the powdery phosphor. Then, the inventors conducted further studies centering on a phosphor component which permits uniform dispersion of the powdery phosphor without unevenness and a resin component which permits a reduction in internal stress. As a result, the inventors found that, where at least one of the oxynitride phosphor and the nitride phosphor (C) which has a smaller specific gravity than the related-art phosphor is used in combination with the aforementioned specific epoxy compound, the sedimentation and the segregation of the phosphor in the encapsulation material is suppressed to ensure the uniform dispersion of the phosphor. Thus, the inventors attained the present invention.

### EFFECTS OF THE INVENTION

As described above, the optical semiconductor element encapsulation resin composition according to the present invention comprises the epoxy resin (A) mainly containing the epoxy compound, and at least one of the oxynitride phosphor and the nitride phosphor (C). Therefore, the phosphor component (C) is uniformly dispersed in the composition without segregation, so that the resin composition has an adequate light diffusion property and a high light transmittance and permits a reduction in internal stress. Therefore, an LED element encapsulated with the resin composition is capable of stably emitting light, and satisfactorily performs its functions.

Where glass powder (D) is further employed and specific relationships between an Abbe number and a refractive index are satisfied, it is possible to minimize reduction in light transmittance and to reduce the thermal expansion coefficient of a product obtained by curing the resin composition. As a result, the internal stress can be reduced as required for heat cycle resistance.

### BRIEF DESCRIPTION OF THE DRAWINGS

FIG. 1 is a chart showing the results of measurement of the excitation and emission spectra of a yellow phosphor of a Ca-α-SiAlON activated by Eu.

FIG. 2 is a chart showing the results of measurement of the excitation and emission spectra of a green phosphor of a β-SiAlON activated by Eu.

FIG. 3 is a chart showing the results of measurement of the excitation and emission spectra of a CASN red phosphor activated by Eu.

FIG. 4 is an explanatory diagram schematically illustrating a measurement system for measuring characteristic properties (secondary light emission peak wavelength, relative intensity of excitation light and variations in chromatic coordinate) of a product obtained by curing an optical semiconductor element encapsulation resin composition.

### BEST MODE FOR CARRYING OUT THE INVENTION

An optical semiconductor element encapsulation resin composition according to the present invention is prepared by employing an epoxy resin (Component (A)) mainly containing a specific epoxy compound, a curing agent (Component (B)) and at least one of an oxynitride phosphor and a nitride phosphor (Component (C)), and is typically used in a powdery form or a tablet form provided by tableting the powdery resin composition. It is noted that an epoxy resin containing the specific epoxy compound alone also falls within the category of the epoxy resin mainly containing the specific epoxy compound.

The specific epoxy compound mainly contained in the epoxy resin (A) is triglycidyl isocyanurate which is an epoxy compound represented by the following structural formula (1). More specifically, the proportion of triglycidyl isocyanurate or the epoxy compound represented by the following structural formula (1) is preferably not less than 40% by weight, more preferably not less than 60% by weight, based on the weight of the entire epoxy resin component. The epoxy resin component (A) may contain triglycidyl isocyanurate alone. If the proportion of triglycidyl isocyanurate is less than 40% by weight, it is difficult to provide sufficient heat and light resistance.

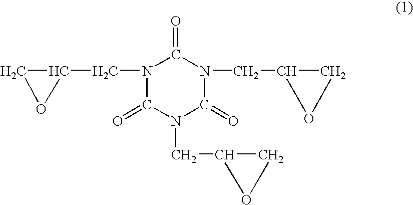

Examples of an epoxy resin other than the aforementioned specific epoxy compound to be used as the epoxy resin component include bisphenol-A epoxy resins, bisphenol-F epoxy resins, novolak epoxy resins such as phenol novolak epoxy resins and cresol novolak epoxy resins, alicyclic epoxy resins, nitrogen-containing cyclic epoxy resins such as hydantoin epoxy resins, hydrogenated bisphenol-A epoxy resins, aliphatic epoxy resins, glycidyl ether epoxy resins, bisphenol-S epoxy resins, biphenyl epoxy resins which are typically of lower water absorption curing type, dicyclic epoxy resins and naphthalene epoxy resins, which may be used either alone or in combination. Among these epoxy resins, the bisphenol-A epoxy resins, the bisphenol-F epoxy resins, the novolak epoxy resins and the alicyclic epoxy resins are preferred, which are excellent in transparency and discoloration resistance.

The aforementioned epoxy resin may be in a solid or liquid form at an ordinary temperature. In general, the epoxy resin to be used preferably has an average epoxy equivalent of 90 to 1,000 and, where it is in a solid form, preferably has a softening temperature of not higher than 160° C. If the epoxy equivalent is less than 90, a product obtained by curing the resulting optical semiconductor element encapsulation resin composition tends to be brittle. If the epoxy equivalent is greater than 1,000, a product obtained by curing the resulting resin composition tends to have a lower glass transition temperature (Tg). In the present invention, the ordinary temperature means a temperature of 25±5° C.

Another transparent thermosetting resin may be used in combination with the aforementioned epoxy resin. Examples of such a resin include unsaturated polyester resins.

Examples of the curing agent (B) to be used in combination with the component (A) include an acid anhydride curing agent and a phenol curing agent. Preferred examples of the acid anhydride curing agent include phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, methylhexahydrophthalic anhydride and methyltetrahydrophthalic anhydride, which may be used either alone or in combination. Among these acid anhydride curing agents, phthalic anhydride, hexahydrophthalic anhydride, tetrahydrophthalic anhydride and methylhexahydrophthalic anhydride are preferred. An acid anhydride having a molecular weight of about 140 to about 200 is preferably used, and a colorless or pale yellow acid anhydride is preferably used as the acid anhydride curing agent.

An example of the phenol curing agent is a phenol novolak resin curing agent.

Besides the acid anhydride curing agent and the phenol curing agent described above, a conventionally known curing agent for the epoxy resin such as an amine curing agent or a compound prepared by partially esterifying the acid anhydride curing agent with an alcohol, or a carboxylic acid curing agent such as hexahydrophthalic acid, tetrahydrophthalic acid or methylhexahydrophthalic acid may be used alone or in combination with the acid anhydride curing agent or the phenol curing agent, as the curing agent (B), depending on its purpose and application. Where the carboxylic acid curing agent is used in combination, for example, the curing speed is increased, thereby improving the productivity. Where any of these curing agents is used, the curing agent may be blended in the same blending ratio (equivalent ratio) as in the case in which the acid anhydride curing agent or the phenol curing agent is used.

The blending ratio between the transparent epoxy resin component (A) and the curing agent (B) is preferably such that an active group (an acid anhydride group or a hydroxyl group) reactive with an epoxy group in the curing agent (B) is present in a proportion of 0.5 to 1.5 equivalents, more preferably 0.7 to 1.2 equivalents, per equivalent of an epoxy group in the transparent epoxy resin component (A). If the proportion of the active group is less than 0.5 equivalents, the resulting optical semiconductor element encapsulation resin composition tends to have a reduced curing speed, and a product obtained by curing the resin composition tends to have a low glass transition temperature (Tg). If the proportion is greater than 1.5 equivalents, the resulting resin composition tends to have a reduced moisture resistance.

In consideration of the durability, examples of the oxynitride phosphor and the nitride phosphor (C), at least one of which is used in combination with the component (A) and the component (B), include oxynitride phosphors obtained by activating an oxynitride crystal by Eu²⁺ ions or other optically active ions and nitride phosphors obtained by activating a nitride crystal by Eu²⁺ ions or other optically active ions. Among these oxynitride phosphors and nitride phosphors, an α-SiAlON phosphor, a β-SiAlON phosphor and a CASN phosphor are preferred from the viewpoint of color rendering properties.

An α-SiAlON of the α-SiAlON phosphor is an inorganic compound obtained by doping an α-Si₃N₄ crystal with ions of a metal M in a solid solution form, partly substituting Si of the α-Si₃N₄ crystal with Al and partly substituting N of the α-Si₃N₄ crystal with 0 while maintaining the crystalline structure of the α-Si₃N₄ crystal. The formulation of the α-SiAlON is represented by the following general formula (α). In the general formula (α), examples of M include Li, Mg, Ca, Y and lanthanoid elements for the α-SiAlON. The α-SiAlON phosphor has a formulation such that ions of a metal M of an M-α-SiAlON are partly substituted with ions of optically active metal A, and is represented by a general formula (Mₓ,A_{y}) (Si,Al)₁₂(O,N)₁₆. Examples of the metal ions A include Mn, Ce, Pr, Nd, Sm, Eu, Tb, Dy, Er, Tm and Yb. Particularly, an inorganic compound (Caₓ,Eu_{y}) (Si,Al)₁₂(O,N)₁₆ obtained by partly substituting Ca of a Ca-α-SiAlON crystal with Eu is a phosphor which is capable of absorbing a wide range of wavelength from 300 nm to 470 nm to emit yellow to orange light having a peak at a wavelength of 570 nm to 600 nm. Therefore, this inorganic compound is suitable for a white LED.

Mₓ(Si,Al)₁₂(O,N)₁₆ (α)

wherein M is Li, Mg, Ca, Y or a lanthanoid element.

A β-SiAlON of the β-SiAlON phosphor is an inorganic compound obtained by partly substituting Si of a β-Si₃N₄ crystal with Al and partly substituting N of the β-Si₃N₄ crystal with O while maintaining the crystalline structure of the β-Si₃N₄ crystal. The formulation of the β-SiAlON is represented by the following general formula (β). Although it was said that the β-SiAlON does not form a solid solution with any metal element M, the inventors of the present invention found that the β-SiAlON forms a solid solution with a very small amount of a metal element. The β-SiAlON crystal is doped with ions of an optically active metal A in a solid solution form to provide a phosphor represented by Si_{6-z}Al_{z}O_{z}N_{8-z}:A. Examples of the metal ions A include Mn, Ce, Pr, Nd, Sm, Eu, Tb, Dy, Er, Tm and Yb. Particularly, a compound Si_{6-z}Al_{z}O_{z}N_{8-z}:Eu obtained by doping the β-SiAlON crystal with Eu is a phosphor which is capable of absorbing a wide range of wavelength from 250 nm to 470 nm to emit green light having a peak at a wavelength of 530 nm to 550 nm. Therefore, this compound is suitable for a white LED (Naoto Hirosaki, et al., Applied Physics Letters, Vol. 86, p. 211905, 2005).

Si_{6-z}Al_{z}O_{z}N_{8-z} (β)

wherein 0<z<4.2.

The term “CASN” of the CASN phosphor is a general term referring to inorganic compounds having the same crystalline structure as CaAlSiN₃. In the case of the crystal of the CASN, it is possible to partly or entirely substitute Ca of CaAlSiN₃ with Mg, Sr, Ba or the like, to partly substitute Si of CaAlSiN₃ with Al and to partly substitute N of CaAlSiN₃ with O, while maintaining the crystalline structure of CaAlSiN₃. An inorganic compound obtained by partly substituting Ca of CaAlSiN₃ with ions of an optically active metal A is fluorescent. This inorganic compound is the CASN phosphor. Examples of the metal ions A include Mn, Ce, Pr, Nd, Sm, Eu, Tb, Dy, Er, Tm and Yb. Particularly, a compound CaAlSiN₃:Eu obtained by doping the CASN crystal with Eu is a phosphor which is capable of absorbing a wide range of wavelength from 250 nm to 500 nm to emit red light having a peak at a wavelength of 600 nm to 670 nm. Therefore, this compound is suitable for a white LED (Naoto Hirosaki, et al., Proceedings of the 65th Applied Physics Meeting, Vol. 3, p. 1283, 2004).

The phosphor component (C), which is at least one of the oxynitride phosphor and the nitride phosphor, has a smaller specific gravity than, for example, a conventional yttrium-aluminum-garnet phosphor activated by Ce (YAG/Ce). Where the phosphor component (C) is used in combination with the epoxy resin component (A) in the present invention, it is possible to suppress segregation of the phosphor component (C) in the production process of the optical semiconductor element encapsulation resin composition and to suppress variations in chromaticity among products molded from the resin composition.

The phosphor component (C), which is at least one of the oxynitride phosphor and the nitride phosphor preferably, has an average particle diameter of 0.5 μm to 50 μm, more preferably 0.8 μm to 20 μm for prevention of lack of filling and agglomeration of particles of the phosphor component. The average particle diameter is measured by means of a particle size distribution measurement apparatus of a laser diffraction scattering type.

The proportion of the at least one of the oxynitride phosphor and the nitride phosphor in the optical semiconductor element encapsulation resin composition is not particularly limited, but depends upon, for example, brightness required for a light emitting diode or the like.

Glass powder (Component (D)) may be blended with the components (A) to (C). Usable as the glass powder (D) is glass powder mainly containing SiO₂, or glass powder mainly containing SiO₂ and B₂O₃. Further, at least one element selected from zinc, titanium, cerium, bismuth, lead and selenium is optionally blended for adjusting the Abbe number of the glass powder. Particularly, it is preferred to blend zinc or titanium so as to approximate the Abbe number of the glass powder (D) to the Abbe number of a product obtained by curing the resin component other than the glass powder (D) and the phosphor component (C). Zinc is typically blended in the form of ZnO, and the proportion of ZnO is preferably 1 to 10% by weight based on the weight of the glass powder. Titanium is typically blended in the form of TiO₂, and the proportion of TiO₂ is preferably 1 to 10% by weight based on the weight of the glass powder.

In order to adjust the refractive index of the glass powder (D), Na_{Z}O, Al₂O₃, CaO, BaO or the like is preferably blended as required.

The glass powder (D) may be obtained, for example, by melting the aforementioned ingredients of the glass powder, rapidly cooling the resulting melt and pulverizing the resulting glass frit by means of a ball mill or the like. The glass powder obtained through the pulverization may be used as it is, but is preferably rounded into spherical glass particles through a surface flame treatment. That is, the spherical glass particles are free from surface bubbles and cracks, so that little light scattering occurs in interfaces between the resin component and the glass particles. Therefore, a product obtained by curing the resulting resin composition has an improved light transmittance.

The resulting glass powder is preferably sieved as having predetermined particle diameters, for example, by means of a sieve or the like. In consideration of the viscosity of the resin component observed when the glass powder is mixed with the resin component and the moldability for prevention of gate clogging during molding, it is preferred that the glass powder (D) has an average particle diameter of 5 μm to 100 μm.

In consideration of the transparency, the moldability and reduction in linear expansion coefficient, the proportion of the glass powder (D) in the optical semiconductor element encapsulation resin composition is preferably 10 to 90% by weight, particularly preferably 20 to 70% by weight. If the proportion is less than 10% by weight based on the weight of the optical semiconductor element encapsulation resin composition, the effect of reducing the linear expansion coefficient is reduced, making it difficult to reduce the stress. If the proportion is greater than 90% by weight, the resulting resin composition tends to suffer from a reduction in fluidity and moldability in transfer molding.

In addition to the components (A) to (C) and the glass powder (D), conventionally employed known additives such as a curing catalyst, an anti-aging agent, a modifier, a silane coupling agent, a defoaming agent, a leveling agent, a mold releasing agent, a dye and a pigment may be blended in the optical semiconductor element encapsulation resin composition according to the present invention.

The curing catalyst is not particularly limited, but examples thereof include tertiary amines such as 1,8-diazabicyclo(5,4,0)undecene-7, triethylenediamine and tri-2,4,6-dimethylaminomethylphenol, imidazoles such as 2-ethyl-4-methylimidazole and 2-methylimidazole, phosphorus compounds such as triphenylphosphine, tetraphenylphosphonium tetraphenylborate and tetra-n-butylphosphonium-o,o-diethyl phosphorodithioate, quaternary ammonium salts, organic metal salts, and derivatives of these compounds, which may be used either alone or in combination. Among these curing accelerators, the tertiary amines, the imidazoles and the phosphorus compounds are preferred.

The proportion of the curing catalyst is preferably 0.01 to 8.0 parts by weight (hereinafter referred to simply as parts), more preferably 0.1 to 3.0 parts, based on 100 parts of the epoxy resin component (A). If the proportion is less than 0.01 parts, it is difficult to provide a sufficient curing accelerating effect. If the proportion is greater than 8.0 parts, a product obtained by curing the resulting resin composition is liable to suffer from discoloration.

Examples of the anti-aging agent include conventionally known anti-aging agents such as phenol compounds, amine compounds, organic sulfur compounds and phosphine compounds. Examples of the modifier include conventionally known modifiers such as glycols, silicones and alcohols. Examples of the silane coupling agent include conventionally known silane coupling agents such as silanes and titanates. Examples of the defoaming agent include conventionally known defoaming agents such as silicones.

In the optical semiconductor element encapsulation resin composition according to the present invention, a relationship between the Abbe number (m1) of a product obtained by curing the resin component other than the phosphor component (C) and the glass powder (D) and the Abbe number (m2) of the glass powder (D) preferably satisfies the following expression (a), particularly preferably the following expression (a′). In the present invention, the Abbe number is the reciprocal of dispersive power, and is expressed by the following expression (x)

−5.0≦m1−m2≦5.0 (a)

wherein m1 is the Abbe number of the product obtained by curing the component other than the components (C) and (D), and m2 is the Abbe number of the component (D).

−3.0≦m1−m2≦3.0 (a′)

wherein m1 is the Abbe number of the product obtained by curing the component other than the components (C) and (D), and m2 is the Abbe number of the component (D).

$$Abbe number = \frac{( refractive index at 589.3 nm ) - 1}{\begin{matrix}( refractive index at 450 nm ) - \\ ( refractive index at 650 nm )\end{matrix}} \qquad ( x )$$

If a difference between the Abbe number (m1) of the product obtained by curing the resin component other than the phosphor component (C) and the glass powder (D) and the Abbe number (m2) of the glass powder (D) is smaller than −5.0 or greater than 5.0, it is difficult to provide proper light transmittance at the respective wavelengths. The Abbe number (m1) of the product obtained by curing the resin component other than the phosphor component (C) and the glass powder (D) may be greater or smaller than the Abbe number (m2) of the glass powder (D).

In the optical semiconductor element encapsulation resin composition according to the present invention, a relationship between the refractive index (n1) of the product obtained by curing the resin component other than the phosphor component (C) and the glass powder (D) and the refractive index (n2) of the glass powder (D) preferably satisfies the following expression (b), and particularly preferably satisfies the following expression (b′) for the light transmittance.

−0.005≦n1−n2≦0.005 (b)

wherein n1 is the refractive index of the product obtained by curing the component other than the components (C) and (D) at a wavelength of 589.3 nm, and n2 is the refractive index of the component (D) at a wavelength of 589.3 nm.

−0.003≦n1−n2≦0.003 (b′)

wherein n1 is the refractive index of the product obtained by curing the component other than the components (C) and (D) at a wavelength of 589.3 nm, and n2 is the refractive index of the component (D) at a wavelength of 589.3 nm.

If a difference between the refractive index (n1) of the product obtained by curing the resin component other than the phosphor component (C) and the glass powder (D) at a wavelength of 589.3 nm and the refractive index (n2) of the glass powder (D) at a wavelength of 589.3 nm is smaller than −0.005 or greater than 0.005, it is difficult to provide proper light transmittance at the respective wavelengths. The refractive index (n1) of the product obtained by curing the resin component other than the phosphor component (C) and the glass powder (D) may be greater or smaller than the refractive index (n2) of the glass powder (D).

In the optical semiconductor element encapsulation resin composition according to the present invention, the product obtained by curing the resin component other than the phosphor component (C) and the glass powder (D) preferably has an Abbe number of, for example, 20 to 65, more preferably 25 to 60, and preferably has a refractive index (nD) of 1.40 to 1.65, more preferably 1.45 to 1.60, as measured at the sodium D spectral line.

A preferred combination of the epoxy resin component (A) and the curing agent (B) for providing the Abbe number and the refractive index in the aforementioned ranges is, fox example, triglycidyl isocyanurate and a bisphenol-A epoxy resin used in combination as the epoxy resin component (A), and an acid anhydride curing agent used as the curing agent (B).

The optical semiconductor element encapsulation resin composition according to the present invention is prepared, for example, in the following manner. Where the optical semiconductor element encapsulation resin composition is provided in a liquid form, for example, the components (A) to (C) are blended with the additives as required and, optionally, further blended with the glass powder. Where the optical semiconductor element encapsulation resin composition is provided in a powdery form or provided in a tablet form by tableting the powdery resin composition, for example, the components are properly blended as in the aforesaid case, then premixed, and melt-kneaded by a kneader. Then, the resulting melt is cooled to room temperature, and the resulting product is pulverized by known means and tableted if necessary.

Meanwhile, the phosphor generally has a greater specific gravity, and is present in an agglomerate form. Therefore, the phosphor is liable to experience sedimentation. If the phosphor is premixed with the liquid resin at an ordinary temperature for potting, sedimentation of the phosphor occurs during the thermosetting of the resin, so that the phosphor is unevenly dispersed in the resulting cured product. Therefore, the phosphor is generally mixed with the resin component in a solid form for uniform dispersion of the phosphor. However, even if the phosphor is blended with the other components of the optical semiconductor element encapsulation resin composition in a powdery form for molding, uneven flow is liable to occur during the molding. If the powdery phosphor is directly added to and mixed with the resin composition in a mixing vessel, the powdery phosphor which has a greater specific gravity is liable to experience sedimentation and segregation when the resulting mixture is received in a molten state. This often results in uneven concentration of the phosphor, so that emitted light is observed as having an uneven color. Therefore, a production method for the optical semiconductor element encapsulation resin composition containing the phosphor component includes a first step of melt-mixing the aforementioned components, and a second step of spreading the melt mixture obtained in the first step into a sheet having a thickness of 2 mm to 70 mm, more preferably having a thickness of 2 mm to 25 mm for prevention of internal gelation due to accumulated heat and, in this state, adjusting the viscosity of the melt mixture in a predetermined temperature atmosphere. In the second step, the viscosity of the resin component except for the phosphor component is preferably maintained at not less than 0.8 Pa·s (at 60° C.). The viscosity is preferably not less than 1.0 Pa·s (at 60° C.) in consideration of variations in surrounding temperature during the adjustment of the viscosity and variations in the specific gravity of the phosphor. The viscosity is measured, for example, by a rheometer (RS-1 available from HAAKE Company).

Where the resin composition produced by this production method is filled in a package at a molding temperature for the molding, the phosphor is uniformly dispersed in the resin composition during the flow of the resin composition by a change in shear rate. However, if the resin composition is kept in a melted state for a long period of time after having been filled in the package, the sedimentation and the segregation of the phosphor is liable to occur. Therefore, a gelation time is preferably set to 10 to 60 seconds for prevention of the sedimentation by performing a gelation test on a hot plate at 150° C., making it possible to prevent the segregation. If the gelation time is shorter than 10 seconds, lack of filling is liable to occur. If the gelation time is longer than 60 seconds, the segregation of the phosphor and voids are liable to occur. The gelation time is more preferably set within a range of 15 to 40 seconds in consideration of the molding cycle and prevention of the lack of filling.

The optical semiconductor element encapsulation resin composition thus produced is employed for encapsulating an optical semiconductor element such as an LED. That is, a method for encapsulating the optical semiconductor element with the optical semiconductor element encapsulation resin composition is not particularly limited, but a known molding method such as an ordinary transfer molding method or a casting method may be employed. Where the optical semiconductor element encapsulation resin composition according to the present invention is in a liquid form, the resin composition is of a so-called two-liquid type which is designed such that at least the epoxy resin component and the curing agent are separately stored and mixed with each other immediately before use. Where the optical semiconductor element encapsulation resin composition according to the present invention is in a powdery form or in a tablet form, the respective components are melt-mixed into B-stage, and the resulting mixture is further heated to be melted for use.

Where the optical semiconductor element is encapsulated with the optical semiconductor element encapsulation resin composition according to the present invention, it is possible to reduce the internal stress, thereby effectively preventing deterioration of the optical semiconductor element and ensuring an excellent light transmittance. Therefore, an optical semiconductor device having the optical semiconductor element encapsulated with the optical semiconductor element encapsulation resin composition according to the present invention is highly reliable and excellent in transparency to satisfactorily perform its functions.

Next, examples of the present invention will be described in conjunction with comparative examples. However, the present invention is not limited to these inventive embodiments.

Prior to production of optical semiconductor element encapsulation resin compositions, the following ingredients were prepared.

### Epoxy Resin-a

Bisphenol-A epoxy resin (having an epoxy equivalent of 650)

### Epoxy Resin-b

Triglycidyl isocyanurate (having an epoxy equivalent of 100) represented by the structural formula (1)

### Acid Anhydride Curing Agent

A mixture of 4-methylhexahydrophthalic anhydride (X) and hexahydrophthalic anhydride (Y) (having a weight ratio of X/Y=7/3 and an anhydride equivalent of 164)

### Curing Catalyst

2-ethyl-4-methylimidazole

### Silane Coupling Agent

Mercaptotrimethoxysilane

### Antioxidant

9,10-dihydro-9-oxa-10-phosphophenanthrene-10-oxide

### Compound Metal Oxide Glass Powder

Spherical glass powder of CaO composition obtained through a flame treatment (containing 51.0% by weight of SiO₂, 20.5% by weight of B₂O₃, 2.9% by weight of ZnO, 15.1% by weight of Al₂O₃, 9.9% by weight of CaO and 0.5% by weight of Sb₂O₃, and having a particle size distribution with an average particle diameter of 35 μm and a maximum particle diameter of 75 μm, and a refractive index of 1.53)

### Powdery Phosphor-a

A yellow phosphor of Ca-α-SiAlON activated by Eu was prepared in the following manner.

To provide a compound represented by a composition formula Ca_{0.75}Eu_{0.0833}(Si,Al)₁₂(O,N)₁₆, powdery silicon nitride having an average particle diameter of 0.5 μm, an oxygen content of 0.93% by weight and an α-type content of 92%, powdery aluminum nitride, calcium carbonate and europium oxide were weighed in amounts of 68.96% by weight, 16.92% by weight, 11.81% by weight and 2.3% by weight, respectively, and mixed with each other for two hours with the use of n-hexane by means of a wet ball mill. Then, the n-hexane was removed by a rotary evaporator to provide a dry powder mixture. The resulting mixture was pulverized with the use of an agate mortar and an agate pestle and then sieved by a 500-μm sieve, and the resulting powder was put in a boron nitride crucible. Then, the crucible was set in an electric oven of graphite resistance heating type. For firing the powder, the electric oven was first evacuated by a diffusion pump to provide a vacuum firing atmosphere, and heated from room temperature to 800° C. at a rate of 500° C. per hour. Then, nitrogen having a purity of 99.999% by volume was introduced into the electric oven at 800° C., and the pressure of the electric oven was adjusted to 1 MPa. In turn, the electric oven was heated up to 1600° C. at a rate of 500° C. per hour, and kept at 1600° C. for eight hours. After the firing, a part of the resulting product was pulverized in an agate mortar, and was analyzed with the use of an X-ray diffractometer (RINT2000 available from Rigaku Corporation), thereby providing an X-ray diffraction pattern. As a result, it was confirmed that the product thus prepared was an α-SiAlON phosphor. The product obtained by the firing was coarsely pulverized, and then sieved by a 60-μm sieve. The resulting powdery product had an average particle diameter of 10 μm as measured by a particle size analyzer (1064 available from CILAS Corporation).

The powdery product was irradiated by a lamp emitting light having a wavelength of 365 nm and, as a result, emission of yellow light was confirmed. The excitation spectrum and the emission spectrum of the powdery product were measured by means of a fluorescent spectrometer (F-4500 available from Hitachi High Technologies Corporation). The measurement results are shown in FIG. 1. Further, it was confirmed that the powdery product was a yellow phosphor. The powdery product had a specific gravity of 3.2 g/cm³.

### Powdery Phosphor-b

A green phosphor of β-SiAlON activated by Eu was prepared in the following manner.

To provide a compound represented by a composition formula Eu_{0.0009}Si_{0.415}Al_{0.015}O_{0.0015}N_{0.568}, powdery silicon nitride having an average particle diameter of 0.5 μm, an oxygen content of 0.93% by weight and an α-type content of 92%, powdery aluminum nitride having a specific surface area of 3.3 m²/g and an oxygen content of 0.79% by weight and powdery europium oxide having a purity of 99.9% were weighed in amounts of 96.17% by weight, 3.03% by weight and 0.8% by weight, respectively, and mixed with each other for two hours with the use of n-hexane by means of a wet ball mill employing a sintered silicon nitride pot and sintered silicon nitride balls. Then, the n-hexane was removed by a rotary evaporator to provide a dry powder mixture. The resulting mixture was pulverized with the use of an agate mortar and an agate pestle and then sieved by a 500-μm sieve. Thus, particle agglomerates having excellent fluidity were provided. The particle agglomerates were naturally dropped into a boron nitride crucible having a size of 20 mm (diameter)×20 mm (height). Then, the crucible was set in an electric oven of graphite resistance heating type. For firing the particle agglomerates, the electric oven was first evacuated by a diffusion pump to provide a vacuum firing atmosphere, and heated from room temperature to 800° C. at a rate of 500° C. per hour. Then, nitrogen having a purity of 99.999% by volume was introduced into the electric oven at 800° C., and the pressure of the electric oven was adjusted to 1 MPa. In turn, the electric oven was heated up to 1900° C. at a rate of 500° C. per hour, and kept at this temperature for two hours. A sample of a product thus synthesized was pulverized with the use of an agate mortar, and the resulting powdery product was analyzed through powder X-ray diffractometry (XRD) employing Cu—K-α radiation with the use of the X-ray diffractometer (RINT2000 available from Rigaku Corporation). The resulting charts indicated that the powdery product had a β-silicon nitride structure.

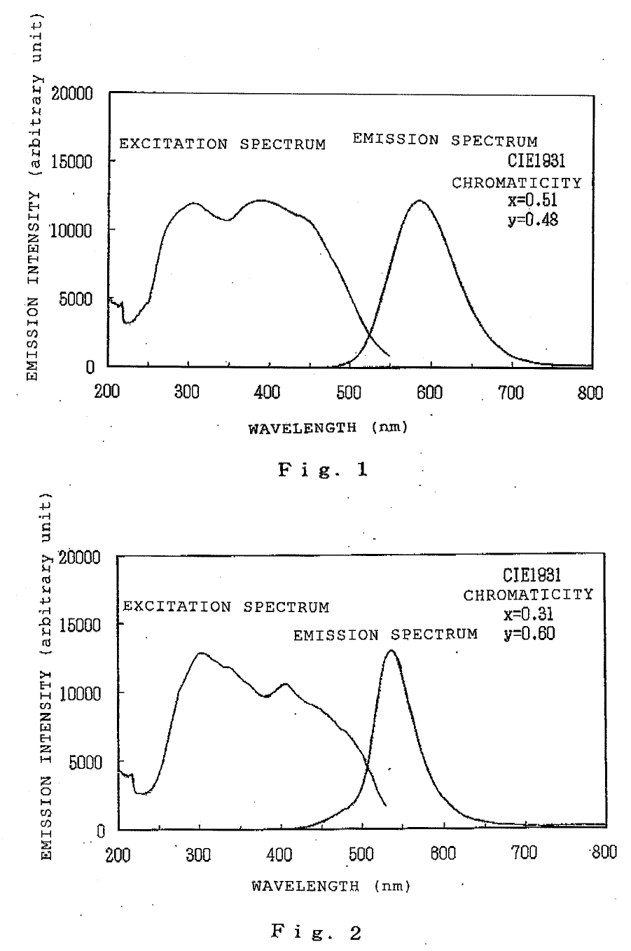

The powdery product was irradiated by a lamp emitting light having a wavelength of 365 nm and, as a result, emission of green light was confirmed. The excitation spectrum and the emission spectrum of the powdery product were measured by means of the fluorescent spectrometer (F-4500 available from Hitachi High Technologies Corporation). The measurement results are shown in FIG. 2. Further, it was confirmed that the powdery product was a green phosphor. The powdery product had a specific gravity of 3.2 g/cm³.

### Powdery Phosphor-c

A red phosphor of CASN activated by Eu was prepared in the following manner.

To provide a compound represented by a composition formula Eu_{0.008}Ca_{0.992}AlSiN₃, powdery silicon nitride having an average particle diameter of 0.5 μm, an oxygen content of 0.93% by weight and an α-type content of 92%, powdery aluminum nitride having a specific surface area of 3.3 m²/g and an oxygen content of 0.79% by weight, powdery calcium carbonate and powdery europium nitride synthesized by nitriding metal europium in ammonia were weighed in amounts of 33.86% by weight, 29.68% by weight, 35.50% by weight and 0.96% by weight, respectively, and mixed with each other for 30 minutes with the use of an agate mortar and an agate pestle. Then, the resulting mixture was sieved by a 500-μm sieve, and the resulting powder was put in a boron nitride crucible having a size of 20 mm (diameter)×20 mm (height). The weighing and the mixing of the powdery materials were carried out in a glove box in which a nitrogen atmosphere was maintained with a moisture content of less than 1 ppm and an oxygen content of less than 1 ppm. Then, the crucible in which the powder mixture was contained was set in an electric oven of graphite resistance heating type. For firing the powder mixture, the electric oven was first evacuated by a diffusion pump to provide a vacuum firing atmosphere, and heated from room temperature to 800° C. at a rate of 500° C. per hour. Then, nitrogen having a purity of 99.999% by volume was introduced into the electric oven at 800° C., and the pressure of the electric oven was adjusted to 1 MPa. In turn, the electric oven was heated up to 1800° C. at a rate of 500° C. per hour, and kept at 1800° C. for two hours. After the firing, the resulting product was coarsely pulverized and further manually pulverized with the use of a sintered silicon nitride crucible and a pestle, and sieved by a 30-μm sieve. Then, a sample of a powdery product thus synthesized was further pulverized in an agate mortar, and analyzed through powder X-ray diffractometry (XRD) employing Cu—K-α radiation by means of the X-ray diffractometer (RINT2000 available from Rigaku Corporation). As a result, it was confirmed that the powdery product had a CaSiAlN₃ phase.

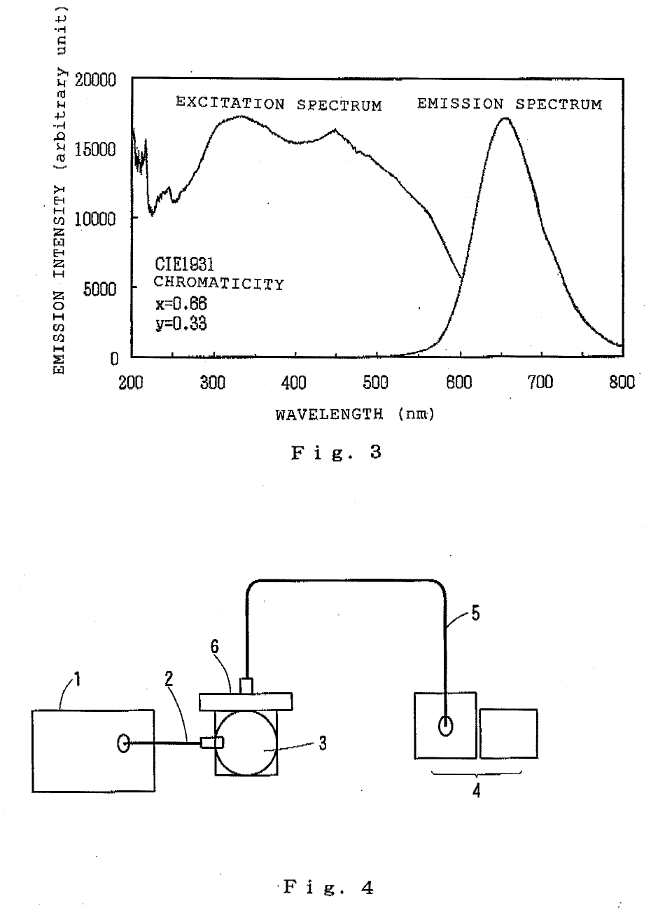

The powdery product was irradiated by a lamp emitting light having a wavelength of 365 nm and, as a result, emission of red light was confirmed. The excitation spectrum and the emission spectrum of the powdery product were measured by means of the fluorescent spectrometer (F-4500 available from Hitachi High Technologies Corporation). The measurement results are shown in FIG. 3. Further, it was confirmed that the powdery product was a red phosphor. The powdery product had a specific gravity of 3.25 g/cm³.

### Powdery Phosphor-d

A powdery YAG/Ce phosphor (having a (Y_{0.8}Gd_{0.2})₃Al₅O₁₂:Ce structure, an average particle diameter of 2.6 μm and a specific gravity of 4.6)

### EXAMPLES

### Examples 1 to 7 and Comparative Examples 1 and 2

Optical semiconductor element encapsulation resin compositions were each prepared by melt-mixing ingredients in proportions as shown in Tables 1 and 2, spreading the resulting melt mixture into a sheet having a thickness of 15±5 mm and, in this state, adjusting the viscosity of the melt mixture in a predetermined temperature atmosphere (at 60° C.) to keep the melt mixture in a semisolid state with the viscosity of a resin component except for a solid or phosphor component being not less than 0.8 Pa·s.

TABLE 1
(parts by weight)

| | | Example | | | | | | |
|---|---|---|---|---|---|---|---|---|
| | | 1 | 2 | 3 | 4 | 5 | 6 | 7 |
| Epoxy resin | a | — | — | — | 60 | — | — | 80 |
| | b | 100 | 100 | 100 | 40 | 100 | 100 | 20 |
| Acid anhydride curing | | 170 | 170 | 170 | 80 | 170 | 170 | 55 |
| agent | | | | | | | | |
| Curing catalyst | | 1 | 1 | 1 | 1 | 1 | 1 | 1 |
| Silane coupling agent | | 1 | 1 | 1 | 1 | 1 | 1 | 1 |
| Antioxidant | | 1 | 1 | 1 | 1 | 1 | 1 | 1 |
| Compound metal oxide | | — | — | — | — | 30 | 280 | — |
| glass powder | | | | | | | | |
| Powdery phosphor | a | 6 | — | — | 4 | 6 | 9 | 4 |
| | b | — | 6 | — | — | — | — | — |
| | c | — | — | 6 | — | — | — | — |
| | d | — | — | — | — | — | — | — |

TABLE 2
(parts by weight)

Comparative Example

| | | 1 | 2 |
|---|---|---|---|
| Epoxy resin | a | 100 | — |
| | b | — | 100 |
| Acid anhydride curing agent | | 25 | 170 |
| Curing catalyst | | 1 | 1 |
| Silane coupling agent | | 1 | 1 |
| Antioxidant | | 1 | 1 |
| Compound metal oxide glass powder | | — | — |
| Powdery phosphor | a | 3 | — |
| | b | — | — |
| | c | — | — |
| | d | — | 8 |

The optical semiconductor element encapsulation resin compositions of Examples and Comparative Examples thus prepared were evaluated for various characteristic properties in the following manner. The results of the evaluation are shown in Tables 3 and 4.

### Gelation Time

An optical semiconductor element encapsulation resin composition (200 mg to 500 mg) as a sample was placed on a hot plate at a predetermined temperature (150° C.), and stirred and thinly spread on the hot plate. A period from melting of the sample to solidification of the sample was measured, which was defined as a gelation time.

### Refractive Index

The refractive index (n1) of a product obtained by curing a resin composition containing components other than a phosphor component and glass powder at 150° C. for four minutes and then at 150° C. for three hours and the refractive index (n2) of the glass powder were measured at a wavelength of 589.3 nm by means of an Abbe refractometer (T2 available from Atago Co., Ltd).

### Abbe Number

The Abbe number (m1) of the product obtained by curing the resin composition containing the components other than the phosphor component and the glass powder at 150° C. for four minutes and then at 150° C. for three hours and the Abbe number (m2) of the glass powder were calculated according to the aforementioned definition based on the refractive indexes measured by means of the Abbe refractometer (T2 available from Atago Co., Ltd).

### Secondary Light Emission Peak Wavelength

A sample (having a diameter of 50 mm and a thickness of 0.4 mm) for evaluation was prepared by transfer-molding an optical semiconductor element encapsulation resin composition at 150° C. for four minutes. The evaluation sample was evaluated for secondary light emission peak wavelength by means of a measurement system (MCPD7000 available from Otsuka Electronics Co., Ltd.) as shown in FIG. 4. More specifically, light of a wavelength of 470 nm from a xenon light source 4 was applied to the evaluation sample 6 through a light projection fiber 5 so as to be passed through the evaluation sample 6. Then, the light was converged on an integrating sphere 3 to be introduced into an MCPD detector 1 through a light receiving fiber 2, and the secondary light emission peak wavelength was detected by the MCPD detector.

### Relative Excitation Light Intensity

A sample (having a diameter of 50 mm and a thickness of 0.4 mm) for evaluation was prepared by transfer-molding an optical semiconductor element encapsulation resin composition at 150° C. for four minutes. The evaluation sample was evaluated for relative excitation light intensity by means of the measurement system (MCPD7000 available from Otsuka Electronics Co., Ltd.) as shown in FIG. 4. More specifically, light of a wavelength of 470 nm from the xenon light source 4 was applied to the evaluation sample 6 through the light projection fiber 5 so as to be passed through the evaluation sample 6. Then, the light was converged on the integrating sphere 3 to be introduced into the MCPD detector 1 through the light receiving fiber 2, and a transmission peak intensity relative to a blank was detected as a relative value by the MCPD detector.

Relative Excitation Light Intensity after Treatment at 150° C. for 72 Hours

A sample (having a diameter of 50 mm and a thickness of 0.4 mm) for evaluation was prepared by transfer-molding an optical semiconductor element encapsulation resin composition at 150° C. for four minutes. The evaluation sample was allowed to stand in an oven at 150° C. for 72 hours, and then evaluated for relative excitation light intensity by means of the measurement system (MCPD7000 available from Otsuka Electronics Co., Ltd.) as shown in FIG. 4. More specifically, light of a wavelength of 470 nm from the xenon light source 4 was applied to the evaluation sample 6 through the light projection fiber 5 so as to be passed through the evaluation sample 6. Then, the light was converged on the integrating sphere 3 to be introduced into the MCPD detector 1 through the light receiving fiber 2, and a transmission peak intensity relative to a blank was detected as a relative value by the MCPD detector.

### Linear Expansion Coefficient

A sample (having a size of 20 mm×5 mm×5 mm (thickness)) for evaluation was prepared by curing an optical semiconductor element encapsulation resin composition at 120° C. for one hour and then at 150° C. for three hours. The glass transmission temperature (Tg) of the sample prepared by the curing was measured at a temperature increasing rate of 2° C./minute by means of a thermal analyzer (TMA-50 available from Shimadzu Corporation), and the linear expansion coefficient of the resin composition was calculated based on the glass transition temperature.

### Variations in Chromatic Coordinate

A sample (having a diameter of 50 mm and a thickness of 0.4 mm) for evaluation of chromaticity was prepared by transfer-molding an optical semiconductor element encapsulation resin composition at 150° C. for four minutes. The chromaticity evaluation sample was evaluated for the chromaticity by means of the measurement system (MCPD7000 available from Otsuka Electronics Co., Ltd.) as shown in FIG. 4. More specifically, light of a wavelength of 470 nm from the xenon light source 4 was applied to the chromaticity evaluation sample 6 through the light projection fiber 5 so as to be passed through the chromaticity evaluation sample 6. In turn, the light was converged on the integrating sphere 3 to be introduced into the MCPD detector 1 through the light receiving fiber 2. Then, the chromaticity (x) was calculated through a chromaticity computation, and variations in chromaticity were determined in the form of a standard deviation (with a sample number of 10).

TABLE 3

| | Example | | | | | | |
|---|---|---|---|---|---|---|---|
| | 1 | 2 | 3 | 4 | 5 | 6 | 7 |
| Gelation time (second) | 35 | 30 | 31 | 30 | 34 | 29 | 30 |
| Difference in refractive index (n1-n2) | — | — | — | — | 0.005 | 0.005 | — |
| Difference in Abbe number (m1-m2) | — | — | — | — | 4.3 | 4.3 | — |
| Secondary light emission peak | 585 | 535 | 650 | 590 | 588 | 587 | 588 |
| wavelength (nm) | | | | | | | |
| Relative excitation light intensity (I.e.) | 0.25 | 0.21 | 0.30 | 0.25 | 0.28 | 0.22 | 0.26 |
| Relative excitation light intensity (I.e.) | 0.23 | 0.19 | 0.29 | 0.23 | 0.26 | 0.21 | 0.24 |
| after treatment at150° C. for 72 hours | | | | | | | |
| Linear expansion coefficient (ppm/° C.) | 61 | 62 | 62 | 64 | 56 | 47 | 63 |
| Variation in chromatic coordinate (σ) | 0.0005 | 0.0004 | 0.0004 | 0.0009 | — | — | 0.0008 |

TABLE 4

Comparative
Example

| | 1 | 2 |
|---|---|---|
| Gelation time (second) | 32 | 33 |
| Difference in refractive index (n1 − n2) | — | — |
| Difference in Abbe number (m1 − m2) | — | — |
| Secondary light emission peak | 585 | 588 |
| wavelength (nm) | | |
| Relative excitation light intensity (I.e.) | 0.24 | 0.33 |
| Relative excitation light intensity (I.e.) | 0.12 | 0.33 |
| after treatment at150° C. for 72 hours | | |
| Linear expansion coefficient (ppm/° C.) | 63 | 65 |
| Variation in chromatic coordinate (σ) | 0.0003 | 0.029 |

As can be understood from the results shown above, a comparison between the relative excitation light intensity and the relative excitation light intensity after the treatment at 150° C. for 72 hours indicates that the resin compositions of Examples were free from significant deterioration in relative excitation light intensity and, therefore, were excellent in heat resistance and light resistance. Further, there was little variation in chromatic coordinate.

In contrast, Comparative Example 1, in which the epoxy resin component contained the bisphenol-A epoxy resin alone, was significantly deteriorated in relative excitation light intensity after the treatment at 150° C. for 72 hours as compared with the relative excitation light intensity. Further, Comparative Example 2 which employed the conventional YAG/Ce phosphor having a greater specific gravity suffered from significant variation in chromatic coordinate due to sedimentation and segregation of the powdery phosphor in the encapsulation material.

1. A resin composition for optical semiconductor element encapsulation comprising the following components (A) to (C):
(A) an epoxy resin mainly containing an epoxy compound represented by the following structural formula (1); 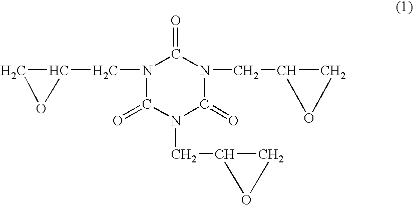
(B) a curing agent; and
(C) at least one of an oxynitride phosphor and a nitride phosphor.

2. An optical semiconductor element encapsulation resin composition as set forth in claim 1, wherein the epoxy compound represented by the structural formula (1) is present in a proportion of not less than 40% by weight in the epoxy resin of the component (A).

3. An optical semiconductor element encapsulation resin composition as set forth in claim 1, wherein the epoxy compound represented by the structural formula (1) is present in a proportion of not less than 60% by weight in the epoxy resin of the component (A).

4. An optical semiconductor element encapsulation resin composition as set forth in claim 1, wherein the oxynitride phosphor of the component (C) is at least one of a phosphor obtained by activating an inorganic compound having a same crystalline structure as α-Si₃N₄ as represented by the following general formula (α) with Eu²⁺ and a phosphor obtained by activating an inorganic compound having the same crystalline structure as β-Si₃N₄ as represented by the following general formula (β) with Eu²⁺:
Mₓ(Si,Al)₁₂(O,N)₁₆ (α)
wherein M is Li, Mg, Ca, Y or a lanthanoid element
Si_{6-z}Al_{z}O_{z}N_{8-z} (β)
wherein 0<z<4.2.

5. An optical semiconductor element encapsulation resin composition as set forth in claim 2, wherein the oxynitride phosphor of the component (C) is at least one of a phosphor obtained by activating an inorganic compound having a same crystalline structure as α-Si₃N₄ as represented by the following general formula (α) with Eu²⁺ and a phosphor obtained by activating an inorganic compound having the same crystalline structure as β-Si₃N₄ as represented by the following general formula (β) with Eu²⁺:
Mₓ(Si,Al)₁₂(O,N)₁₆ (α)
wherein M is Li, Mg, Ca, Y or a lanthanoid element;
Si_{6-z}Al_{z}O_{z}N_{8-z} (β)
wherein 0<z<4.2.

6. An optical semiconductor element encapsulation resin composition as set forth in claim 3, wherein the oxynitride phosphor of the component (C) is at least one of a phosphor obtained by activating an inorganic compound having a same crystalline structure as α-Si₃N₄ as represented by the following general formula (α) with Eu²⁺ and a phosphor obtained by activating an inorganic compound having the same crystalline structure as β-Si₃N₄ as represented by the following general formula (β) with Eu²⁺:
Mₓ(Si,Al)₁₂(O,N)₁₆ (α)
wherein M is Li, Mg, Ca, Y or a lanthanoid element;
Si_{6-z}Al_{z}O_{z}N_{8-z} (β)
wherein 0<z<4.2.

7. The optical semiconductor element encapsulation resin composition as set forth in claim 1, wherein the nitride phosphor of component (C) is a red phosphor obtained by activating an inorganic compound having the same crystalline structure as CaAlSiN₃ crystal with Eu²⁺.

8. An optical semiconductor element encapsulation resin composition as set forth in claim 2, wherein the nitride phosphor of the component (C) is a red phosphor obtained by activating an inorganic compound having the same crystalline structure as CaAlSiN₃ crystal with Eu²⁺.

9. An optical semiconductor element encapsulation resin composition as set forth in claim 3, wherein the nitride phosphor of the component (C) is a red phosphor obtained by activating an inorganic compound having the same crystalline structure as CaAlSiN₃ crystal with Eu²⁺.

10. An optical semiconductor element encapsulation resin composition as set forth in claim 1, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

11. An optical semiconductor element encapsulation resin composition as set forth in claim 2, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

12. An optical semiconductor element encapsulation resin composition as set forth in claim 3, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

13. An optical semiconductor element encapsulation resin composition as set forth in claim 4, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

14. An optical semiconductor element encapsulation resin composition as set forth in claim 5, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

15. An optical semiconductor element encapsulation resin composition as set forth in claim 6, further comprising the following component (D) in addition to the components (A) to (C);
(D) glass powder,
wherein a relationship between an Abbe number (m1) of a product obtained by curing components of the optical semiconductor element encapsulation resin composition other than the components (C) and (D) and an Abbe number (m2) of the component (D) satisfies the following expression (a):
−5.0≦m1−m2≦5.0 (a)
wherein m1 is the Abbe number of the product obtained by curing the components other than the components (C) and (D), and m2 is the Abbe number of the component (D),
wherein a relationship between a refractive index (n1) of the product obtained by curing the components of the optical semiconductor element encapsulation resin composition other than the components (C) and (D) and a refractive index (n2) of the component (D) satisfies the following expression (b):
−0.005≦n1−n2≦0.005 (b)
wherein n1 is a refractive index of the product obtained by curing the components other than the components (C) and (D) at a wavelength of 589.3 nm, and n2 is a refractive index of the component (D) at a wavelength of 589.3 nm.

16. An optical semiconductor device comprising an optical semiconductor element encapsulated with an optical semiconductor element encapsulation resin composition as recited in claim 1.

17. An optical semiconductor device comprising an optical semiconductor element encapsulated with an optical semiconductor element encapsulation resin composition as recited in claim 2.

18. An optical semiconductor device comprising an optical semiconductor element encapsulated with an optical semiconductor element encapsulation resin composition as recited in claim 3.

19. An optical semiconductor device comprising an optical semiconductor element encapsulated with an optical semiconductor element encapsulation resin composition as recited in claim 4.

20. An optical semiconductor device comprising an optical semiconductor element encapsulated with an optical semiconductor element encapsulation resin composition as recited in claim 5.
